(19) United States
(12) Patent Application Publication
(10) Pub. No.: US 2024/0256328 A1
(43) Pub. Date: Aug. 1, 2024

(54) PREVENTING BACK-TO-BACK FLIPS OF A BIT IN BIT FLIPPING DECODING

(71) Applicant: Micron Technology, Inc., Boise, ID (US)

(72) Inventors: Mustafa N. Kaynak, San Diego, CA (US); Sivagnanam Parthasarathy, Carlsbad, CA (US)

(21) Appl. No.: 18/419,352

(22) Filed: Jan. 22, 2024

Related U.S. Application Data
(60) Provisional application No. 63/481,691, filed on Jan. 26, 2023.

(51) Int. Cl. G06F 9/48

(52) U.S. Cl. CPC G06F 9/485

(57) ABSTRACT

Methods, systems, and apparatuses mitigate a stall condition in an iterative bit flipping decoder. A codeword is received and current bit is selected. In response to detecting the risk of the stall condition and further in response to determining the current bit satisfies the bit flipping criterion, it is determined that the current bit was flipped in a previous iteration. The flipping of the current bit is bypassed in response to determining the current bit was flipped in the previous iteration.

### CROSS-REFERENCE TO RELATED APPLICATION

The present application claims the benefit of U.S. Provisional Patent Application No. 63/481,691 filed on Jan. 26, 2023, which is incorporated by reference herein in its entirety.

### TECHNICAL FIELD

The present disclosure generally relates to error correction in memory subsystems, and more specifically, relates to efficiently preventing back-to-back flips of a bit in bit flipping decoding.

### BACKGROUND ART

A memory subsystem can include one or more memory devices that store data. The memory devices can be, for example, non-volatile memory devices and volatile memory devices. In general, a host system can utilize a memory subsystem to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory subsystem in accordance with some embodiments of the present disclosure.

FIG. 2 illustrates a block diagram of an exemplary table including a stall pattern that is detected during error correction of a codeword in accordance with some embodiments.

FIG. 3 is a flow diagram of an example method to mitigate a stall condition in iterative decoders by preventing back-to-back bit flips in accordance with some embodiments of the present disclosure.

FIG. 4 is a flow diagram of another example method to mitigate a stall condition in iterative decoders by preventing back-to-back bit flips in accordance with some embodiments of the present disclosure.

FIG. 5 is a block diagram of an example computer system in which embodiments of the present disclosure can operate.

### DETAILED DESCRIPTION

Aspects of the present disclosure are directed to efficiently preventing back-to-back flips of a bit in a bit flipping decoding process for a memory subsystem. A memory subsystem can be a storage device, a memory module, or a hybrid of a storage device and memory module.

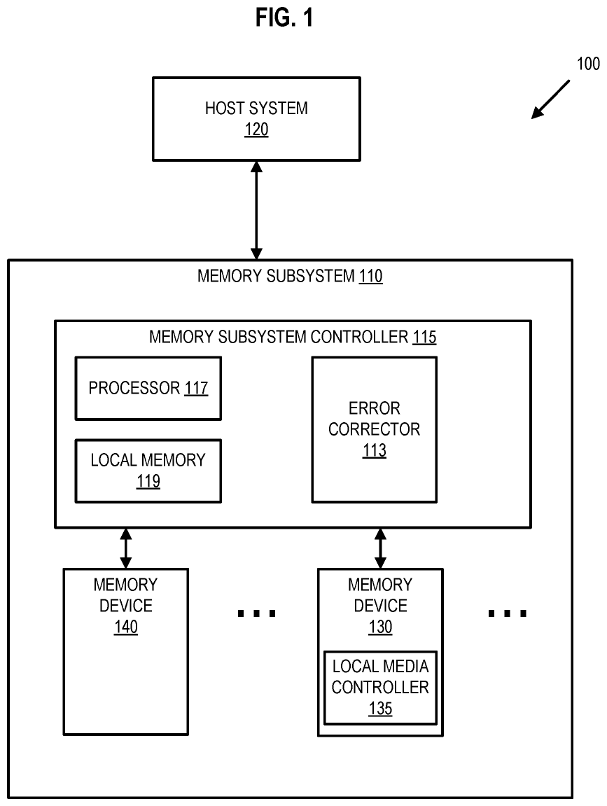

Examples of storage devices and memory modules are described below in conjunction with FIG. 1. In general, a host system can utilize a memory subsystem that includes one or more components, such as memory devices that store data. The host system can provide data to be stored at the memory subsystem and can request data to be retrieved from the memory subsystem.

A memory device can be a non-volatile memory device. A non-volatile memory device is a package of one or more dice. One example of non-volatile memory devices is a negative- and

(NAND) memory device. Other examples of non-volatile memory devices are described below in conjunction with FIG. 1. The dice in the packages can be assigned to one or more channels for communicating with a memory subsystem controller. Each die can consist of one or more planes. Planes can be grouped into logic units (LUN). For some types of non-volatile memory devices (e.g., NAND memory devices), each plane consists of a set of physical blocks, which are groups of memory cells to store data. A cell is an electronic circuit that stores information.

Depending on the cell type, a cell can store one or more bits of binary information, and has various logic states that correlate to the number of bits being stored. The logic states can be represented by binary values, such as “0” and “1”, or combinations of such values. There are various types of cells, such as single-level cells (SLCs), multi-level cells (MLCs), triple-level cells (TLCs), and quad-level cells (QLCs). For example, an SLC can store one bit of information and has two logic states.

Low-Density Parity Check (LDPC) codes are commonly used for enabling error correction in memory subsystems. LDPC codes are a class of highly efficient linear block codes that include single parity check (SPC) codes. LDPC codes have a high error correction capability and can provide performance close to channel capacity. The MinSum algorithm (MSA), which is a simplified version of a belief propagation algorithm, can be used for decoding LDPC codes. MSA-based decoders, however, use a relatively high amount of energy per bit (e.g., pico-Joule per bit) for decoding codewords. As a result, MSA-based decoders are not well suited for energy conscious applications, such as mobile applications.

A bit flipping (BF) decoder iteratively determines an energy function for each bit in a codeword and flips the bit when the energy function satisfies a bit flipping criterion/threshold. The energy function represents the reliability of the current state of a bit, e.g., in terms of the number of satisfied parities for the bit, the number of unsatisfied parities for the bit, whether the current state of the bit matches the state of the bit when read from memory, etc. BF decoders use less energy per bit at the expense of providing a lower error correction capability when compared to the error correction capability of MSA-based decoders. Lower error correction capability is an obstacle to the deployment of BF decoders for replacing MSA-based decoders.

Additionally, a BF decoder can get stuck in a stall condition, e.g., in which a pattern of the count of unsatisfied parities repeats and additional iterations of the decoder do not enable the BF decoder to further reduce the count of unsatisfied parities and complete the decoding process. When a BF decoder is in a stall condition, it often flips the same set of bits in back-to-back iterations. Such stall conditions affect the Quality of Service (QoS) and latency of the memory subsystem. A BF decoder unable to exit a stall condition can trigger escalated error handling operations, even when the raw bit error rate (RBER) is low, which results in worse QoS and higher latency.

Aspects of the present disclosure address the above and other deficiencies by efficiently preventing flips of a bit in back-to-back iterations in the BF decoding process. While a decoder can track bit flips by storing and updating indications for each bit of the codeword, such an approach would substantially increase the memory consumed by the BF decoder. Additionally, evaluating bits for flips in back-to-back iterations prior to there being a risk of a stall condition increases complexity and latency without a corresponding improvement in performance. Accordingly, the memory subsystem described herein efficiently prevents flips of a bit in back-to-back iterations in response to detecting a risk of a stall condition. For example, the memory subsystem can detect a risk of a stall condition upon reaching or exceeding a threshold iteration count. In response to detecting a risk of a stall condition, the memory subsystem tracks bit flips for a subset of bits in the codeword. For example, in a given iteration, it is likely that the memory subsystem will flip, at most, a minority of bits in a codeword. As such, the memory subsystem uses a limited amount of memory (i.e., less memory than would be required to track flips of all bits of a codeword) to store indications of which bits are flipped in a given iteration, allowing the memory subsystem to bypass flipping those bits in a subsequent iteration without an excessive increase in memory consumed by the BF decoding process.

FIG. 1 illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory subsystems 110. In some embodiments, the host system 120 is coupled to different types of memory subsystems 110. FIG. 1 illustrates one example of a host system 120 coupled to one memory subsystem 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory subsystem 110, for example, to write data to the memory subsystem 110 and read data from the memory subsystem 110.

The host system 120 can be coupled to the memory subsystem 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory subsystem 110. The host system 120 can further utilize an NVM Express (NVMe) interface to access components (e.g., memory devices 130) when the memory subsystem 110 is coupled with the host system 120 by the PCIe interface. The physical host interface can provide an interface for passing control, address, data, and other signals between the memory subsystem 110 and the host system 120. FIG. 1 illustrates a memory subsystem 110 as an example. In general, the host system 120 can access multiple memory subsystems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory devices such as NAND type memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory subsystem controller 115 (or controller 115 for simplicity) can communicate with the memory devices 130 to perform operations such as reading data, writing data, or erasing data at the memory devices 130 and other such operations (e.g., in response to commands scheduled on a command bus by controller 115). The memory subsystem controller 115 can include hardware such as one or more integrated circuits and/or discrete components, a buffer memory, or a combination thereof. The hardware can include digital circuitry with dedicated (i.e., hard-coded) logic to perform the operations described herein. The memory subsystem controller 115 can be a microcontroller, special purpose logic circuitry (e.g., a field programmable gate array (FPGA), an application specific integrated circuit (ASIC), etc.), or another suitable processor.

The memory subsystem controller 115 can include a processing device 117 (processor) configured to execute instructions stored in a local memory 119. In the illustrated example, the local memory 119 of the memory subsystem controller 115 includes an embedded memory configured to store instructions for performing various processes, operations, logic flows, and routines that control operation of the memory subsystem 110, including handling communications between the memory subsystem 110 and the host system 120.

In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the memory subsystem controller 115, in another embodiment of the present disclosure, a memory subsystem 110 does not include a memory subsystem controller 115, and can instead rely upon external control (e.g., provided by an external host, or by a processor or controller separate from the memory subsystem 110).

In general, the memory subsystem controller 115 can receive commands or operations from the host system 120 and can convert the commands or operations into instructions or appropriate commands to achieve the desired access to the memory devices 130 and/or the memory device 140. The memory subsystem controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory subsystem controller 115 can further include host interface circuitry to communicate with the host system 120 via the physical host interface. The host interface circuitry can convert the commands received from the host system into command instructions to access the memory devices 130 and/or the memory device 140 as well as convert responses associated with the memory devices 130 and/or the memory device 140 into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the memory subsystem controller 115 and decode the address to access the memory devices 130.

In some embodiments, the memory devices 130 include local media controllers 135 that operate in conjunction with memory subsystem controller 115 to execute operations on one or more memory cells of the memory devices 130. An external controller (e.g., memory subsystem controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

The memory subsystem 110 includes error corrector 113 that mitigates stall conditions. In some embodiments, the controller 115 includes at least a portion of the error corrector 113. For example, the controller 115 can include a processor 117 (processing device) configured to execute instructions stored in local memory 119 for performing the operations described herein. In some embodiments, an error corrector 113 is part of the host system 120, an application, or an operating system.

In some implementations, the error corrector 113 is operative to encode and decode data stored in the memory device (e.g., an encoder and/or decoder). Encoding data using an error correcting code (ECC) allows for correction of erroneous data bits when the data is retrieved from the memory device. For example, the error corrector 113 can encode data received from the host system 120 and store the data and parity bits as codewords in the memory device 130. The error corrector 113 decodes data stored in the memory device 130 to identify and correct erroneous bits of the data before transmitting corrected data to the host system 120. Although illustrated as a single component that can perform encoding and decoding of data, the error corrector 113 can be provided as separate components. In some embodiments, the error corrector 113 encodes data according to a low-density parity-check (LDPC) code. The error corrector 113 decodes the codewords stored in the memory device 130 based on a BF decoder. As described below, the error corrector 113 prevents flips of a bit in back-to-back iterations in the BF decoding process in response to detecting a risk of a stall condition. Further details with regard to the operations of the error corrector 113 are described below.

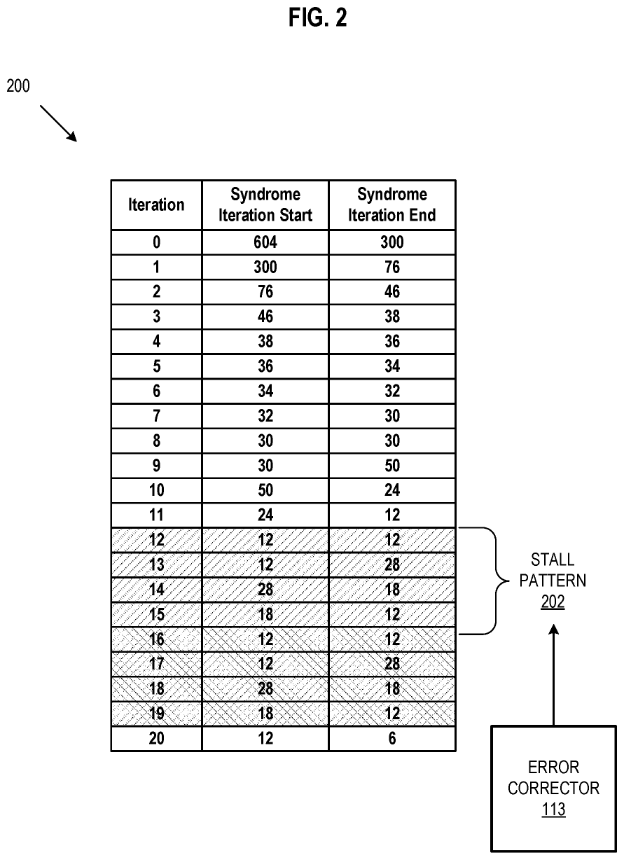

FIG. 2 illustrates a block diagram of an exemplary table 200 including a stall pattern that is detected during error correction of a codeword, in accordance with some embodiments. The error corrector 113 decodes a codeword, attempting to correct errors for multiple iterations. As an example, the table 200 shows syndromes at the start and end of iterations of the error corrector 113. A syndrome indicates a number of parity violations in a codeword. At the initial iteration, 0, the syndrome at the start of the iteration is 604 and the syndrome at the end of the iteration is 300. The error corrector 113 performs a subsequent error correction iteration, iteration 1. At iteration 1, a syndrome iteration start is 300 and a syndrome iteration end is 76. In this example, the BF decoding process of the error corrector 113 starts oscillating (i.e., enters a stall condition) at iteration 12 and the period of oscillation is 4. The stall pattern 202 can be repeated a second time (from iteration 16 to iteration 19). In one embodiment, the error corrector 113 tracks the syndrome for each of a number of sequential iterations and determines there is a risk of stall condition when detecting repetition of syndrome values, such as stall pattern 202. In other embodiments, the error corrector 113 determines there is a risk of a stall condition when the iteration count satisfies a threshold value (e.g., the iteration count reaches or exceeds a threshold value). Upon detecting the risk of a stall condition, the error corrector 113 updates one or more bit flipping rules (e.g., preventing back-to-back bit flips), resulting in breaking out of the stall condition at the end of iteration 20. The detection of a stall condition and update to the bit flipping rule(s) are described in further detail below.

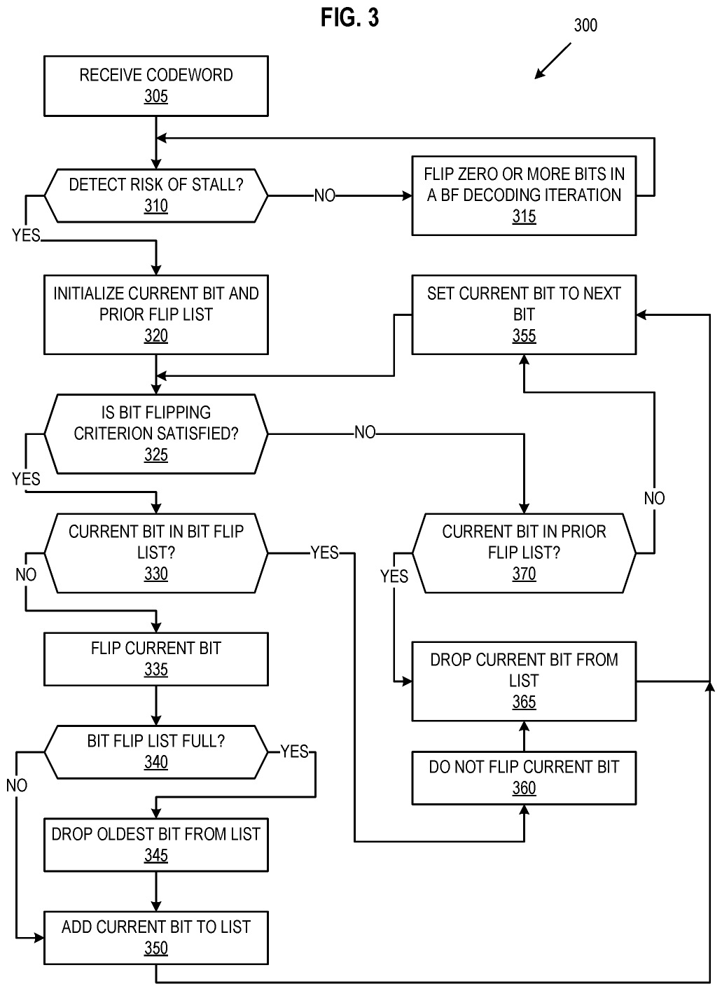

FIG. 3 is a flow diagram of an example method 300 to mitigate a stall condition in a decoder of a memory subsystem by preventing back-to-back bit flips in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the error corrector 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible. The operations of the method 300 will be described with reference to the stall pattern of FIG. 2 as an exemplary stall pattern that can occur during error correction of a codeword. The illustrated embodiments should be understood only as simple examples, other stall patterns can occur.

At operation 305, the processing device receives a codeword from a memory device, e.g., memory device 130 or memory device 140. In some embodiments, the codeword is received as a result of the execution of a read request from a host system 120. The codeword includes a combination of data bits and parity check bits. For example, the parity check bits are stored in the memory device along with the data bits.

At operation 310, the processing device detects if there is a risk of a stall condition in the iterations of decoding. In some embodiments, the processing device detects a risk of a stall condition by monitoring syndromes that result from the error correction of the codeword in the multiple iterations, and detecting a stall pattern, e.g., stall pattern 202, in the syndromes that result from the error correction of the codeword in consecutive iterations from the multiple iterations. For example, the error corrector 113 can store multiple consecutive syndromes generated during iterations of error correction of a codeword and compare successive sets of these syndromes to identify a stall pattern that repeats over multiple sets of iterations. The error corrector 113 can identify the stall pattern 202 as a repeating pattern between iterations 12-15 and iterations 16-19.

In some embodiments, the processing detects a risk of the stall condition in multiple iterations by hashing multiple syndromes that result from the error correction of the codeword in the multiple iterations and comparing the hash value with a hash value resulting from hashing other syndromes resulting from the error correction of the codeword in other iterations. For example, the error corrector 113 can generate a hash value from the syndromes of iterations 12-15, and another hash value from the syndromes of iterations 16-19. The error corrector 113 compares the two hash values to determine that the iterations 12-15 and the iterations 16-19 have a similar pattern that is repeating.

In another embodiment, the processing device detects a risk of a stall condition by determining an iteration count threshold is satisfied. A BF decoder usually corrects errors quickly and a current iteration count that does not trigger a stopping criterion but is equal to or greater than the iteration count threshold can indicate a potential stall condition. For example, referring to table 200, the error corrector 113 can use an iteration count threshold of 19 iterations.

In yet another embodiment, the processing device detects a risk of a stall condition by determining an iteration count threshold is satisfied and a parity violation count threshold is satisfied. A small number of parity violations at or above a threshold iteration count can also indicate a potential stall condition. Continuing the example above, referring to table 200, the error corrector 113 can use an iteration count threshold of 19 iterations. In detecting the parity violation count threshold being satisfied (e.g., a syndrome less than or equal to 20 for table 200) when the iteration count threshold is also satisfied (e.g., a current iteration count of 19 or more iterations), the error corrector 113 determines that a stall condition is present.

In some embodiments, the processing device detects a risk of a stall condition using a combination of one or more thresholds and monitoring syndromes for a repeating pattern. For example, the error corrector 113 can store and compare groups of consecutive syndromes in response to determining an iteration count threshold is satisfied and/or an iteration count threshold and parity violation count threshold is satisfied.

In response to determining there is not a risk of a stall condition, the method proceeds to operation 315 to perform an ordinary iteration of error correcting the codeword. Otherwise, in response to detecting a risk of a stall condition, the method 300 proceeds to operation 320.

At operation 315, the processing device proceeds with an iteration of bit flipping decoding on the codeword. For example, the error corrector 113 includes or uses a bit flipping decoder that performs an iteration of the decoding process, flipping bits within the codeword based on a set of bit flipping rules. The processing device performs an error correction iteration on the codeword to obtain an initial corrected codeword. During an iteration, the processing device determines locations of potentially erroneous bits in the codeword and flips one or more of these bits to obtain an updated codeword (e.g., using an energy function and bit flipping criterion, as described above). For example, the error corrector 113 flips bits in the codeword during iteration 0 of table 200.

Upon completing an iteration, the processing device determines whether a stop condition/criterion is satisfied. A stop criterion can include an indication that no errors are detected for the codeword. In some embodiments, the stop criterion can include a null syndrome indicating that the codeword no longer includes erroneous bits. In some embodiments, the stop criterion can include a maximum number of iterations (i.e., the maximum iteration count) or a maximum amount of time. For example, the processing device is operative to perform the maximum number of iterations (e.g., 30 iterations, 40 iterations, 100 iterations, etc.), and when this number of iterations is performed, the resulting codeword is output, regardless of whether the codeword still includes erroneous bits or not. When the stop criterion is satisfied, the error corrector 113 outputs the corrected codeword or an indication of failure if the processing device was unable to decode the codeword. For example, the error corrector 113 can transmit the corrected codeword to the host 120. In another example, an indication of failure can trigger a different error correction process or the transmission of an error message to the host 120.

At operation 320, in response to detecting a risk of a stall condition, the processing device initializes a current bit and a memory or data structure to store a bit flip list to track flips in a prior iteration. For example, the error corrector 113 can perform an iteration of BF decoding by determining if a bit flipping criterion is satisfied for a bit at a time based on an increasing order of index within the codeword, a decreasing order of index within the codeword, a random order, etc. In some embodiments, the error corrector 113 uses different orders between different iterations. Using the order of decoding for the current iteration, the error corrector 113 determines the current bit to evaluate for a potential flip.

Additionally, the error corrector 113 clears a bit flip list, data structure, or other memory used to track bit flips in prior iterations. For example, the bit flip list can track prior bit flips by an index value or other indication of which bit or bits were flipped in an iteration. Maintenance of the bit flip list is described further below.

At operation 325, the processing device determines if a bit flipping criterion is satisfied for the current bit. For example, the error corrector 113 compares the energy function for the current bit with a bit flipping threshold value and, when the energy function exceeds the threshold, determines the bit flipping criterion is satisfied. In other embodiments, the bit flipping criterion is satisfied when the energy function is less than the bit flipping threshold value. If the bit flipping criterion is satisfied for the current bit, the method 300 proceeds to operation 330. If the bit flipping criterion is not satisfied for the current bit, the method 300 proceeds to operation 370.

At operation 330, in response to the bit flipping criterion being satisfied for the current bit, the processing device determines if an indication of a prior flip of the current bit is in the bit flip list. For example, the error corrector 113 parses the bit flip list for the index of the current bit. If an index, identifier, or other indication of the current bit is not in the bit flip list, the method 300 proceeds to operation 335. If an index, identifier, or other indication of the current bit is in the bit flip list, the method 300 proceeds to operation 360.

At operation 335, in response to a lack of indication of the current bit in the bit flip list, the processing device flips the current bit. For example, the error corrector 113 determines that the current bit satisfies a bit flipping criterion and the current bit was not flipped in the prior iteration, so the error corrector 113 flips the current bit from a value of “0” to a value “1” or from a value of “1” to a value “0.”

At operation 340, the processing device determines if the bit flip list is full. As described above, the bit flip list is maintained with a limited amount of memory. For example, the bit flip list can only store a number of indications to represent a subset of the bits of the codeword (i.e., that is less than all bits of the codeword). As a result, the greater the number of bits flips in an iteration, the more likely the bit flip list can reach a full state. If the bit flip list is full, the method 300 proceeds to operation 345. If the bit flip list is not full, the method 300 proceeds to operation 350.

At operation 345, the processing device removes the oldest bit indicator from the bit flip list. For example, the error corrector 113 maintains the bit flip list as a first-in, first-out (FIFO) list and, when the list is full, removes the entry that has been in the list for the greatest amount of time. In other embodiments, the error corrector 113 removes an indicator at random or using another selection criterion.

At operation 350, in response to flipping the current bit, the processing device adds an indication of the current bit to the bit flip list. For example, the error corrector 113 adds the index of the current bit within the codeword or another indicator for the current bit to the bit flip list to enable the prevention of back-to-back bit flips for the current bit between the current iteration and the subsequent iteration.

At operation 355, the processing device selects the next bit in the codeword to serve as the current bit. As described above, the error corrector 113 can use a predetermined or random order to evaluate the bits of the codeword. If all bits of the codeword have been evaluated in the current iteration, the error corrector determines whether to perform another iteration of error correcting the codeword. For example, as described above, the error corrector 113 outputs the corrected codeword or an indication of failure when a stop criterion is satisfied. If a stop criterion is not satisfied, the error corrector 113 selects a current bit for evaluation of the next iteration and the method 300 returns to operation 325.

At operation 360, in response to detecting an indication of the current bit in the bit flip list, the processing device bypasses the flipping of the current bit. For example, the bit flip list indicates the current bit was flipped in the prior iteration of decoding. As a result, despite the current bit satisfying the bit flipping criterion, the error corrector 113 determines to not flip the current bit to avoid flipping the current bit in back-to-back iterations to reduce the likelihood of continuing a stall condition.

At operation 365, in response to detecting an indication of the current bit in the bit flip list and bypassing the flipping of the current bit in the current iteration, the processing device drops the current bit from the bit flip list. For example, the error corrector 113 deletes an entry in the bit flip list that includes the index or other indicator for the current bit. Additionally, the error corrector 113 can remove the current bit from the bit flip list in response to determining the bit flipping criterion for the current bit is not satisfied as described below.

At operation 370, in response to determining the bit flipping criterion for the current bit is not satisfied, the processing device determines if an indication of the current bit is in the bit flip list. For example, as described with reference to operation 330, the error corrector 113 parses the bit flip list for the index or other indicator for the current bit in the bit flip list. Additionally, when the bit flipping criterion is not satisfied, the error corrector 113 does not flip the current bit.

If an index, identifier, or other indication of the current bit is not in the bit flip list, the method 300 proceeds to operation 355 to select the next bit for evaluation, determine if a stop criterion is satisfied, or proceed to the next iteration. If an index, identifier, or other indication of the current bit is in the bit flip list, the method 300 proceeds to operation 365. For example, the error corrector 113 deletes the entry in the bit flip list that includes the index or other indicator for the current bit in response to the bit flipping criterion not being satisfied and, as a result, the current bit not being flipped in the current iteration.

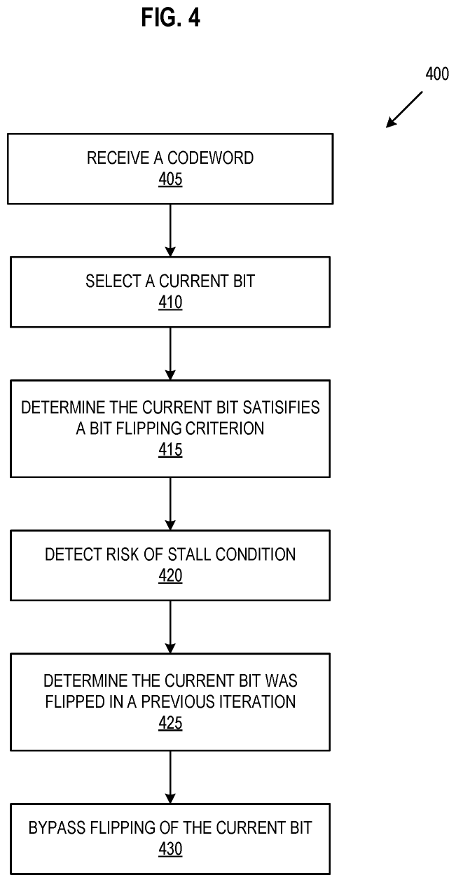

FIG. 4 is a flow diagram of another example method 400 to mitigate a stall condition in iterative decoders by preventing back-to-back bit flips in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the error corrector 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing device receives a codeword from the memory device. For example, the error corrector 113 receives the codeword as a result of the execution of a read request from a host system 120 as described above with reference to operation 305.

At operation 410, the processing device selects a current bit in the codeword for evaluation. For example, the error corrector 113 evaluates bits in a predetermined or random order as described above with reference to operation 320.

At operation 415, the processing device determines a bit flipping criterion is satisfied for the current bit. For example, the error corrector 113 compares the energy function for the current bit with a bit flipping threshold value or otherwise determines the state of the bit is unreliable as described above with reference to operation 325.

At operation 420, the processing device detects a risk of a stall condition is present in the iterations of bit flipping decoding. For example, the error corrector 113 detects a stall condition as described above with reference to operation 310.

At operation 425, the processing device determines the current bit was flipped in a previous iteration. For example, the error corrector 113 determines an index, identifier, or other indication of the current bit is in the bit flip memory, as described above with reference to operation 330.

At operation 430, in response to determining the current bit was flipped in the previous iteration, the processing device bypasses the flipping of the current bit. For example, the error corrector 113 does not flip the current bit, despite the current bit satisfying the bit flipping criterion, to avoid flipping the current bit in back-to-back iterations as described above with reference to operation 360.

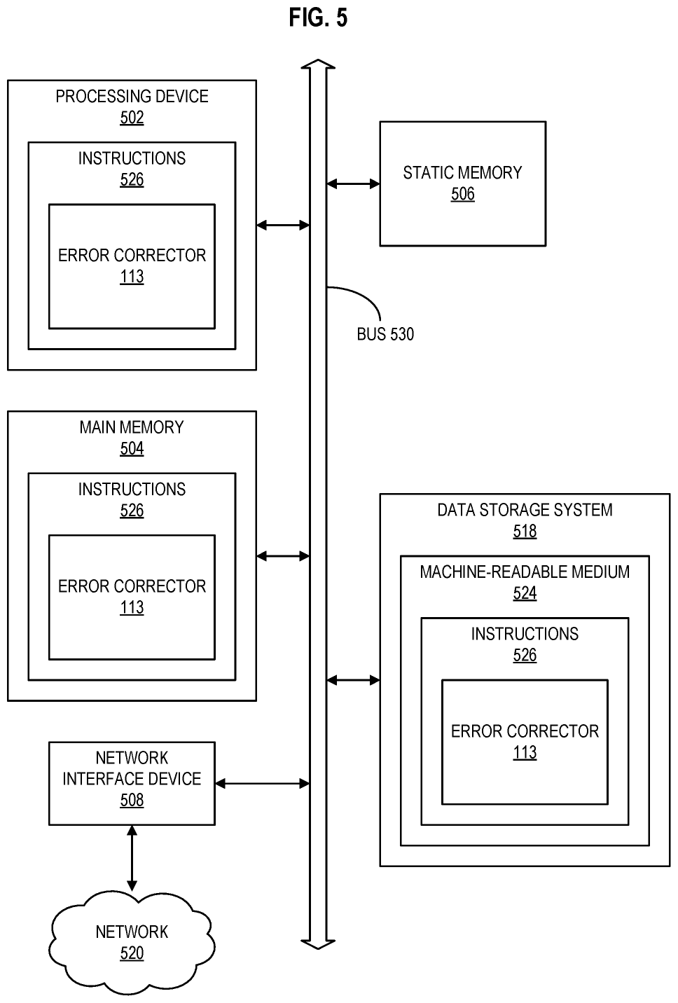

FIG. 5 illustrates an example machine of a computer system 500 within which a set of instructions for causing the machine to perform any one or more of the methodologies discussed herein, can be executed. In some embodiments, the computer system 500 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the error corrector 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory subsystem 110 of FIG. 1.

In one embodiment, the instructions 526 include instructions to implement functionality corresponding to an error corrector (e.g., the error corrector 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, can carry out the computer-implemented methods 300 and 400 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
receiving a codeword from a memory device, wherein the codeword includes a plurality of bits and decoding the codeword includes flipping one or more bits over multiple iterations of bit flipping decoding;
selecting a current bit of the plurality of bits in a current iteration of bit flipping;
determining the current bit satisfies a bit flipping criterion;
detecting a risk of a stall condition in the multiple iterations;
determining the current bit was flipped in a previous iteration of bit flipping in response to detecting the risk of the stall condition and further in response to determining the current bit satisfies the bit flipping criterion; and
bypassing flipping of the current bit in response to determining the current bit was flipped in the previous iteration.

2. The method of claim 1, wherein determining the current bit was flipped in the previous iteration includes detecting an indication in a bit flipping memory the current bit was previously flipped, the method further comprising:
removing the indication in the bit flipping memory the current bit was previously flipped in response to bypassing flipping of the current bit.

3. The method of claim 1, further comprising:
setting the current bit to a next bit of the plurality of bits; and
removing an indication in a bit flipping memory the current bit was previously flipped in response to determining the current bit does not satisfy the bit flipping criterion.

4. The method of claim 1, further comprising:
setting the current bit to a next bit of the plurality of bits;
determining the current bit was not flipped in a previous iteration of bit flipping in response to determining the current bit satisfies the bit flipping criterion; and
flipping the current bit in response to determining the current bit satisfies the bit flipping criterion and was not flipped in the previous iteration.

5. The method of claim 4, further comprising:
adding an indication in a bit flipping memory that the current bit was flipped, wherein the indication is one of a plurality of indications in the bit flipping memory evaluated in a subsequent iteration of bit flipping decoding to determine if a subsequent current bit in the subsequent iteration was previously flipped.

6. The method of claim 5, further comprising:
removing an oldest indication in the bit flipping memory in response to determining there is insufficient storage for the indication that the current bit was flipped.

7. The method of claim 1, wherein detecting the risk of the stall condition includes determining that an iteration count of the multiple iterations satisfies an iteration count threshold.

8. A non-transitory computer-readable storage medium comprising instructions that, when executed by a processing device, cause the processing device to:
receive a codeword from a memory device, wherein the codeword includes a plurality of bits and decoding the codeword includes flipping one or more bits over multiple iterations of bit flipping decoding;
select a current bit of the plurality of bits in a current iteration of bit flipping;
determine the current bit satisfies a bit flipping criterion;
detect a risk of a stall condition in the multiple iterations;
determine the current bit was flipped in a previous iteration of bit flipping in response to detecting the risk of the stall condition and further in response to determining the current bit satisfies the bit flipping criterion; and
bypass flipping of the current bit in response to determining the current bit was flipped in the previous iteration.

9. The non-transitory computer-readable storage medium of claim 8, wherein determining the current bit was flipped in the previous iteration includes detecting an indication in a bit flipping memory the current bit was previously flipped, and wherein the processing device is further to:
remove the indication in the bit flipping memory the current bit was previously flipped in response to bypassing flipping of the current bit.

10. The non-transitory computer-readable storage medium of claim 8, wherein the processing device is further to:
setting the current bit to a next bit of the plurality of bits; and
removing an indication in a bit flipping memory the current bit was previously flipped in response to determining the current bit does not satisfy the bit flipping criterion.

11. The non-transitory computer-readable storage medium of claim 8, wherein the processing device is further to:
set the current bit to a next bit of the plurality of bits;
determine the current bit was not flipped in a previous iteration of bit flipping in response to determining the current bit satisfies the bit flipping criterion; and
flip the current bit in response to determining the current bit satisfies the bit flipping criterion and was not flipped in the previous iteration.

12. The non-transitory computer-readable storage medium of claim 11, wherein the processing device is further to:
add an indication in a bit flipping memory that the current bit was flipped, wherein the indication is one of a plurality of indications in the bit flipping memory evaluated in a subsequent iteration of bit flipping decoding to determine if a subsequent current bit in the subsequent iteration was previously flipped.

13. The non-transitory computer-readable storage medium of claim 12, wherein the processing device is further to:
remove an oldest indication in the bit flipping memory in response to determining there is insufficient storage for the indication that the current bit was flipped.

14. The non-transitory computer-readable storage medium of claim 8, wherein detecting the risk of the stall condition includes determining that an iteration count of the multiple iterations satisfies an iteration count threshold.

15. A system comprising:
a memory device; and
a processing device, operatively coupled with the memory device, to:
receive a codeword from a memory device, wherein the codeword includes a plurality of bits and decoding the codeword includes flipping one or more bits over multiple iterations of bit flipping decoding;
select a current bit of the plurality of bits in a current iteration of bit flipping;
determine the current bit satisfies a bit flipping criterion;
detect a risk of a stall condition in the multiple iterations, wherein detecting the risk of the stall condition includes determining that an iteration count of the multiple iterations satisfies an iteration count threshold;
determine the current bit was flipped in a previous iteration of bit flipping in response to detecting the risk of the stall condition and further in response to determining the current bit satisfies the bit flipping criterion; and
bypass flipping of the current bit in response to determining the current bit was flipped in the previous iteration.

16. The system of claim 15, wherein determining the current bit was flipped in the previous iteration includes detecting an indication in a bit flipping memory the current bit was previously flipped, and wherein the processing device is further to:
remove the indication in the bit flipping memory the current bit was previously flipped in response to bypassing flipping of the current bit.

17. The system of claim 15, wherein the processing device is further to:
setting the current bit to a next bit of the plurality of bits; and
removing an indication in a bit flipping memory the current bit was previously flipped in response to determining the current bit does not satisfy the bit flipping criterion.

18. The system of claim 15, wherein the processing device is further to:
set the current bit to a next bit of the plurality of bits;
determine the current bit was not flipped in a previous iteration of bit flipping in response to determining the current bit satisfies the bit flipping criterion; and
flip the current bit in response to determining the current bit satisfies the bit flipping criterion and was not flipped in the previous iteration.

19. The system of claim 18, wherein the processing device is further to:
add an indication in a bit flipping memory that the current bit was flipped, wherein the indication is one of a plurality of indications in the bit flipping memory evaluated in a subsequent iteration of bit flipping decoding to determine if a subsequent current bit in the subsequent iteration was previously flipped.

20. The system of claim 19, wherein the processing device is further to:
remove an oldest indication in the bit flipping memory in response to determining there is insufficient storage for the indication that the current bit was flipped.
